(19) United States
(12) Patent Application Publication
(10) Pub. No.: US 2010/0213577 A1
(43) Pub. Date: Aug. 26, 2010

(54) SEMICONDUCTOR ELECTRONIC DEVICE AND PROCESS OF MANUFACTURING THE SAME

(75) Inventors: Sadahiro Kato, Tokyo (JP); Yoshihiro Sato, Tokyo (JP); Masayuki Iwami, Tokyo (JP); Takuya Kokawa, Tokyo (JP)

Correspondence Address: TUROCY & WATSON, LLP, 127 Public Square, 57th Floor, Key Tower, CLEVELAND, OH, 44114, US

(73) Assignee: FURUKAWA ELECTRIC CO., LTD., Tokyo (JP)

(21) Appl. No.: 12/712,729

(22) Filed: Feb. 25, 2010

(30) Foreign Application Priority Data
Feb. 26, 2009 (JP) 2009-44754

(51) Int. Cl. H01L 29/20; H01L 29/06; H01L 21/20

(52) U.S. Cl. 257/615; 438/478; 257/E21.09; 257/E29.089; 257/E29.024

(57) ABSTRACT

A semiconductor electronic device comprises a substrate; a buffer layer that comprises composite laminations of which a first semiconductor layer, that is formed of a compound semiconductor of a nitride system, that has a lattice constant to be as smaller than that of such the substrate, and that has a coefficient of thermal expansion to be as larger than that of such the substrate, and a second semiconductor layer that is formed of a compound semiconductor of a nitride system are formed as alternately on to such the substrate; a semiconductor operation layer that is formed of a compound semiconductor of a nitride system and that is formed on to such the buffer layer; and a dislocation reduction layer, which comprises a lower layer region and an upper layer region that are formed at any location at an inner side of such the buffer layer and that comprise an interface of a concave and convex shape therebetween, at which a threading dislocation that draws from such the lower layer region toward such the upper layer region is bending at such the interface, wherein such the second semiconductor layer is comprised of a laminated layers as alternately of a third semiconductor layer that has a lattice constant to be as smaller than that of such the substrate and that has a coefficient of thermal expansion to be as larger than that of such the substrate, and of a fourth semiconductor layer that has a lattice constant to be as smaller than that of such the third semiconductor layer and that has a coefficient of thermal expansion to be as larger than that of such the substrate, and an average of such the lattice constants in the second semiconductor layer is to be smaller than that of such the first semiconductor layer, and an average of such the coefficients of thermal expansion in the second semiconductor layer is to be as larger than that of such the substrate.

### CROSS-REFERENCE TO RELATED APPLICATIONS

This application claims priority to Japanese patent application Serial No. 2009-44754, filed on Feb. 26, 2009, the entire content of which is incorporated herein by reference.

### TECHNICAL FIELD

The present invention relates to a semiconductor electronic device for which a compound semiconductor of a nitride system is made use, and the same relates to a process of manufacturing such the semiconductor electronic device.

### BACKGROUND ART

A compound semiconductor of a nitride system that is expressed by a chemical formula of an AlₓIn_{y}Ga_{1-x-y}AsᵤPᵥN₁₋ᵤ₋ᵥ (here 0≦x≦1, 0≦y≦1, x+y≦1, 0≦u≦1, 0≦v≦1 and u+v≦1), that is an electronic device of such as a field effect transistor which is made use of a compound semiconductor of a GaN system or the like, is paid attention as a solid state device that is available to be operated even in an environment at a higher temperature to be close to 400° C. In the meantime however, it is difficult to manufacture a single crystal substrate of such the compound semiconductor of the GaN system that has a diameter to be as larger with comparing to that for Si or for a GaAs. And hence the electronic device that is made use of the compound semiconductor of the GaN system is manufactured with making use of a substrate which is formed of such as a silicon carbide (an SiC) or a sapphire or a zinc oxide (ZnO) or silicon (Si) or the like. And then the substrate that is formed of Si in particular is remarkably effective as the substrate for the usage of the electronic device, because it is able to obtain such the substrate with having the diameter to be as larger at a low price.

In the meantime however, there is a difference to be as excessively large for between a lattice constant of Si and that of the GaN and for between a coefficient of thermal expansion of Si and that of the GaN. And then thereby becoming existing a tensile strain to be as larger at an inner side of a GaN layer in a case of performing an epitaxial growth of such the GaN layer directly on to a Si substrate. And hence it may become a cause by which a warp may be generated to be as a concave shape for all over an epitaxial substrate in which the GaN layer is formed by the epitaxial growth, or by which a crystalline property may become worsened. Moreover, in a case where such the strain is larger that is existing at the inner side a crack may become generated in such the GaN layer. And then therefore a buffer layer is to be provided in usual as a strain relaxation layer at between the Si substrate and the GaN layer. Further, it is effective for such the buffer layer to be made use of a laminated structure of a GaN layer and an AlN layer (refer to the patent document 1 to 3).

Here, FIG. 11 is a cross sectional view for exemplary showing one example of a field effect transistor of a GaN system that comprises a buffer layer which has a laminated structure. And then such a field effect transistor (200) that is shown in FIG. 11 is designed to be as a high electron mobility transistor (HEMT), and then the same comprises: a substrate (10) that is formed of a single crystal of Si; an intercalated layer (30) that is formed of an AlN to be formed by making use of a process of an epitaxial crystal growth, such as a method of a metalorganic chemical vapor deposition (an MOCVD) or the like, on to such the substrate (10); and then a buffer layer (70) that is formed by performing a lamination of a GaN layer (71) and an AlN layer (72) as alternately. Moreover, such the field effect transistor (200) further comprises: a semiconductor operation layer (40) on to the buffer layer (70), in which an electron transit layer (41) that is formed of a GaN as an undope and an electron supplying layer (42) that is formed of an AlGaN as an (n) type and a contact layer (43) that is formed of a GaN as an (n+) type are laminated one after the other in such the order; a source electrode (51) and a drain electrode (52) that are formed on to the contact layer (43); an open part (43a) that is formed on to the contact layer (43); and a gate electrode (53) that is formed on to the electron supplying layer (42) via the open part (43a). And then by forming the composite lamination of the GaN layer (71) and the AlN layer (72) to be as the buffer layer it becomes able to perform the epitaxial growth of the GaN layer (41) in which there is not occurred any crack at all and that has the crystalline property to be as excellent on to the substrate (10) that is formed of the single crystal of Si. Further, it becomes able to obtain an improvement regarding the warp for all over such the epitaxial substrate. Furthermore, such the buffer layer is not to be limited to such the composite lamination of the GaN layer and the AlN layer. And then even in a case of making use of a composite lamination of AlGaN layers that individually have a composition to be as different from each other it becomes able to obtain an advantage to be as similar thereto if there is existing a strain with an amount to be as properly for between each of such the composite lamination.

[Patent Document 1] The Japanese Patent No. 3960957

[Patent Document 2] The Japanese Patent Application Publication No. 2003-059948

[Patent Document 3] The Japanese Patent Application Publication No. 2007-088426

### DISCLOSURE OF THE INVENTION

### Problems to be Solved by the Invention

Here, it is important to obtain an ON resistance of an electronic device to be as lower in order to realize an electric power supply device by making use of the electronic device that comprises the epitaxial layer of the compound semiconductor of the GaN system.

In a case where a dislocation exists at an inner side of a semiconductor crystal an electron mobility becomes to be decreased. And then therefore it is necessary to reduce a dislocation density to be as low as possible in a semiconductor operation layer in particular in order to reduce an ON resistance. Moreover, among the threading dislocations that are generated at a vicinity of the substrate due to the strain of between the substrate and the epitaxial layer and then draw toward an upper side there are some that draw till reaching to such the semiconductor operation layer, though the others are disappeared and then decreased at an inner side of the buffer layer that comprises the composite lamination which is described above. And then therefore a technology is required by which the dislocation density in the semiconductor operation layer becomes to be further reduced, in order to perform a further reduction of the ON resistance of the electronic device.

In the meantime however, in accordance with the result that the present inventors have performed the examination as closely regarding the buffer layer that comprises the composite lamination of the GaN layer and the AlN layer and then found out that there are some cases where the dislocations become to be further increased at an inner side of the AlN layer in a case where a layer thickness of the AlN layer is designed to be thicker in order such as to suppress a warp or the like for the buffer layer that comprises such the composite lamination.

Here, FIG. 12 is a view for showing an image by making use of a transmission electron microscope (TEM) regarding a cross section of a buffer layer in accordance with a field effect transistor that comprises a structure as similar to that in accordance with FIG. 11. Moreover, in accordance with FIG. 12 the symbols from E1 to E3 individually designate the GaN layers, and in the meantime, the symbols of F1 and F2 individually designate the AlN layers, respectively. Further, the arrow therein designates a direction of an excitation (11-20). Still further, a layer thickness of each of the GaN layers from the E1 to the E3 is determined here to be as approximately 400 nanometers respectively, and in the meantime a layer thickness of each of the AlN layers as the F1 and the F2 is determined here to be as approximately fifty nanometers respectively. Still further, in accordance with FIG. 12 the white line designates a threading dislocation. And then such the threading dislocations are decreased once at the inner side of the E1 as the GaN layer at the substrate side, in the meantime however the threading dislocations become to be increased at the inner side of the F1 as the AlN layer as more than that in the E1 as the GaN layer, and then a plurality of threading dislocations are existed in the inner side of the E2 as the GaN layer, that are shown in FIG. 12. Furthermore, the threading dislocations become to be increased at the inner side of the F2 as the AlN layer as more than that at the inner side of the E2 as the GaN layer, and then the threading dislocations become to be existed at the inner side of the E3 as the GaN layer with the number to be as further larger, that are similar to each of which is described above.

And thus as a result of the dislocations that are increased at the inner side of the AlN layer the dislocation density cannot help but become to be increased again that is decreased once at the inner side of the buffer layer which is at the lower side than such the AlN layer. And then as a result, there are obtained the following problems that it is not able to realize the reduction of the dislocation density to be as sufficiently for the electron transit layer which is the most important for the operation of the electronic device, and that it is not able to obtain the ON resistance to be lower as sufficiently.

And then therefore the present invention is provided with having regard to the subjects that are described above, and then an objective is to provide a semiconductor electronic device and a process of manufacturing such the semiconductor electronic device, by which it becomes able to reduce a warp to be as smaller and to reduce an ON resistance to be as lower.

### Means for Solving the Problem

In order to solve the subjects that are mentioned above, and in order to complete the objective, a first aspect of a semiconductor electronic device in accordance with the present invention is characterized in that such the semiconductor electronic device comprises: a substrate; a buffer layer that comprises composite laminations of which a first semiconductor layer, that is formed of a compound semiconductor of a nitride system, that has a lattice constant to be as smaller than that of such the substrate, and that has a coefficient of thermal expansion to be as larger than that of such the substrate, and a second semiconductor layer that is formed of a compound semiconductor of a nitride system are formed as alternately on to such the substrate; a semiconductor operation layer that is formed of a compound semiconductor of a nitride system and that is formed on to such the buffer layer; and a dislocation reduction layer, which comprises a lower layer region and an upper layer region that are formed in between such the substrate and such the semiconductor operation layer and that comprise an interface of a concave and convex shape therebetween, at which a threading dislocation that draws from such the lower layer region toward such the upper layer region is bending at such the interface, and which is formed of a compound semiconductor of a nitride system, wherein such the second semiconductor layer is comprised of a laminated layers as alternately of a third semiconductor layer that has a lattice constant to be as smaller than that of such the substrate and that has a coefficient of thermal expansion to be as larger than that of such the substrate, and of a fourth semiconductor layer that has a lattice constant to be as smaller than that of such the third semiconductor layer and that has a coefficient of thermal expansion to be as larger than that of such the substrate, and an average of such the lattice constants in the second semiconductor layer is smaller than that of such the first semiconductor layer, and an average of such the coefficients of thermal expansion in the second semiconductor layer is larger than that of such the substrate.

Moreover, a second aspect of the semiconductor electronic device in accordance with the present invention is characterized in that according to the first aspect it is proven true that an (x1) is smaller than an (x2), in a case where a composition of such the third semiconductor layer is expressed by a chemical formula of an Alₓ₁In_{y1}Ga_{1-x1-y1}Asᵤ₁Pᵥ₁N₁₋ᵤ₁₋ᵥ₁ (here 0≦x1≦1, 0≦y1≦1, x1+y1≦1, 0≦u1≦1, 0≦v1≦1 and u1+v1≦1) and a composition of such the fourth semiconductor layer is expressed by a chemical formula of an Alₓ₂In_{y2}Ga_{1-x2-y2}Asᵤ₂Pᵥ₂N₁₋ᵤ₂₋ᵥ₂ (here 0≦x2≦1, 0≦y2≦1, x2+y2≦1, 0≦u2≦1, 0≦v2≦1 and u2+v2≦1).

Further, a third aspect of the semiconductor electronic device in accordance with the present invention is characterized in that according to the first aspect such the third semiconductor layer has a layer thickness to be as thicker than or equal to 0.5 nanometer, but thinner than or equal to fifty nanometers.

Still further, a fourth aspect of the semiconductor electronic device in accordance with the present invention is characterized in that according to the first aspect such the fourth semiconductor layer has a layer thickness to be as thicker than or equal to 0.5 nanometer, but thinner than or equal to fifty nanometers.

Still further, a fifth aspect of the semiconductor electronic device in accordance with the present invention is characterized in that according to the first aspect such the second semiconductor layer has a layer thickness to be as thicker than or equal to five nanometers, but thinner than or equal to 500 nanometers.

Still further, a sixth aspect of the semiconductor electronic device in accordance with the present invention is characterized in that according to the first aspect a sum of the number of the layers of such the third semiconductor layers and such the fourth semiconductor layers in such the second semiconductor layer is between five and thirty.

Still further, a seventh aspect of the semiconductor electronic device in accordance with the present invention is characterized in that according to the first aspect such the average of such the lattice constants of such the second semiconductor layer is smaller than or equal to a mean value of the lattice constant of such the first semiconductor layer and the lattice constant of such the fourth semiconductor layer.

Still further, an eighth aspect of the semiconductor electronic device in accordance with the present invention is characterized in that according to the first aspect such the substrate is comprised of any one of silicon and silicon carbide and zinc oxide.

Still further, a ninth aspect of the semiconductor electronic device in accordance with the present invention is characterized in that according to any one of the first to the eighth aspects the semiconductor electronic device further comprises: an intercalated layer, that is formed directly on to such the substrate, that has a lattice constant to be as smaller than that of such the first semiconductor layer, that has a coefficient of thermal expansion to be as larger than that of such the substrate, and that is formed of a compound semiconductor of a nitride system.

Still further, a tenth aspect of a process of manufacturing a semiconductor electronic device in accordance with the present invention is characterized in that such the process of manufacturing the semiconductor electronic device comprises the steps of: forming a buffer layer on to a substrate as a processing of a formation of such the buffer layer, that is to comprise composite laminations of which a first semiconductor layer, that is to be formed of a compound semiconductor of a nitride system, that is to have a lattice constant to be as smaller than that of such the substrate, and that is to have a coefficient of thermal expansion to be as larger than that of such the substrate, and a second semiconductor layer that is to be formed of a compound semiconductor of a nitride system are to be formed as alternately; and forming a semiconductor operation layer as a processing of a formation of such the semiconductor operation layer, that is to be formed of a compound semiconductor of a nitride system and that is to be formed on to such the buffer layer, wherein such the processing of the formation of such the buffer layer further comprises a processing of a formation of a dislocation reduction layer in order to form a lower layer region at any location at an inner side of such the buffer layer that is to be formed of a compound semiconductor of a nitride system and that is to comprise a most top surface of a concave and convex shape, and in order to form an upper layer region that is to have a most top surface to be as smooth on to such the lower layer region that is formed in such a manner, at such the processing of the formation of such the buffer layer a third semiconductor layer that is to have a lattice constant to be as smaller than that of such the substrate and that is to have a coefficient of thermal expansion to be as larger than that of such the substrate and a fourth semiconductor layer that is to have a lattice constant to be as smaller than that of such the third semiconductor layer and that is to have a coefficient of thermal expansion to be as larger than that of such the substrate are to be laminated as alternately, and such the second semiconductor layer is to be formed for an average of the lattice constants in order to be smaller than that of such the first semiconductor layer and for an average of the coefficients of thermal expansion in order to be as larger than that of such the substrate.

Furthermore, an eleventh aspect of a process of manufacturing a semiconductor electronic device in accordance with the present invention is characterized in that according to the tenth aspect such the process of manufacturing the semiconductor electronic device comprises the additional step of: forming an intercalated layer as a processing of a formation of such the intercalated layer, that is to be formed directly on to such the substrate, that is to have a lattice constant to be as smaller than that of such the first semiconductor layer, that is to have a coefficient of thermal expansion to be as larger than that of such the substrate, and that is to be formed of a compound semiconductor of a nitride system.

### Effect of the Invention

In accordance with the present invention it becomes able to reduce a dislocation density by making use of the dislocation reduction layer. Moreover, it becomes able to prevent from an increase of the dislocations at the inner side of the buffer layer, and then it becomes able to reduce the dislocation density in the semiconductor operation layer, with maintaining an effect of suppressing the warp of the buffer layer. And then therefore it becomes able to obtain the advantage by which it becomes able to perform the reduction of the warp to be as smaller and to perform the reduction of the ON resistance to be as lower.

### BRIEF DESCRIPTION OF THE DRAWINGS

FIG. 1 is a cross sectional view exemplary showing a field effect transistor in accordance with the first embodiment.

FIG. 2 is a cross sectional view exemplary showing a detailed structure of a second semiconductor layer that is shown in FIG. 1.

FIG. 3 is an explanatory drawing showing a function of a dislocation reduction layer.

FIG. 4 is a drawing exemplary showing an appearance of which a threading dislocation is increasing in accordance with a field effect transistor that is shown in FIG. 11.

FIG. 5 is a drawing exemplary showing an appearance of which an increasing of a threading dislocation is prevented in accordance with the field effect transistor that is shown in FIG. 1.

FIG. 6 is a view showing a TEM image regarding a cross section of a field effect transistor that comprises a structure of a multilayer laminated layer and a GaN layer as an undope on after the other in such the order on to a substrate that is formed of Si.

FIG. 7 is an explanatory drawing showing one example of a process of forming a dislocation reduction layer.

FIG. 8 is an explanatory drawing showing one example of a process of forming a dislocation reduction layer.

FIG. 9 is an explanatory drawing showing one example of a process of forming a dislocation reduction layer.

FIG. 10 is an explanatory drawing showing one example of a process of forming a dislocation reduction layer.

FIG. 11 is a cross sectional view exemplary showing one example of a field effect transistor of a GaN system that comprises a buffer layer which has a multilayer laminated structure.

FIG. 12 is a view showing a TEM image regarding a cross section of a buffer layer in accordance with a field effect transistor that comprises a structure as similar to that in accordance with FIG. 11.

### DESCRIPTION OF THE REFERENCE SYMBOLS

10 SUBSTRATE

20, 70 BUFFER LAYER

211 to 218 A FIRST SEMICONDUCTOR LAYER

22 A SECOND SEMICONDUCTOR LAYER

221 A THIRD SEMICONDUCTOR LAYER

222 A FOURTH SEMICONDUCTOR LAYER

30 INTERCALATED LAYER

40 SEMICONDUCTOR OPERATION LAYER

41 ELECTRON TRANSIT LAYER

42 ELECTRON SUPPLYING LAYER

43 CONTACT LAYER

43a OPEN PART

51 SOURCE ELECTRODE

52 DRAIN ELECTRODE

53 GATE ELECTRODE

60 DISLOCATION REDUCTION LAYER

60a INTERFACE

61 LOWER LAYER REGION

61a AMORPHOUS LAYER

61b GROWTH CORE

62 UPPER LAYER REGION

71 GaN LAYER

72 AlN LAYER

100, 200 FIELD EFFECT TRANSISTOR

A SUBSTRATE

B MULTILAYER LAMINATED LAYER

C, E1 to E3 GaN LAYER

D1 to D8 THREADING DISLOCATION

F1, F2 AN LAYER

P1, P2 POINT

### BEST MODE FOR CARRYING OUT THE INVENTION

An embodiment of a semiconductor electronic device and of a process of manufacturing such the semiconductor electronic device in accordance with the present invention will be described in detail below, in reference to the drawings. However, the present invention is not to be limited to such the embodiment. Moreover, a similar component and element is to be designated as properly with making use of the similar symbol in each of the drawings.

### The First Embodiment

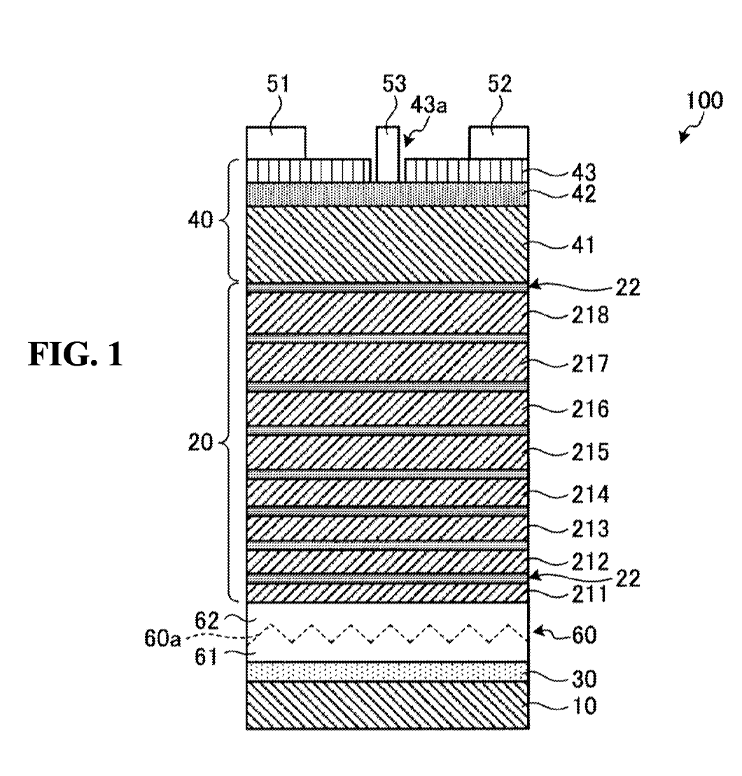

FIG. 1 is a cross sectional view for exemplary showing a field effect transistor regarding the first embodiment in accordance with the present invention. And then such a field effect transistor (100) is designed to be as the HEMT that comprises: a substrate (10) which is formed of a single crystal of Si with an (111) plane to be as a principal surface plane; an intercalated layer (30) that is formed on to the substrate (10); a buffer layer (20) that is formed on to the intercalated layer (30); a semiconductor operation layer (40) that is formed on to the buffer layer (20); a source electrode (51), a drain electrode (52) and a gate electrode (53) that are formed on to the semiconductor operation layer (40). Moreover, the same further comprises a dislocation reduction layer (60) that is formed at a location directly under the buffer layer (20).

Further, the intercalated layer (30) is formed of an AN as an undope. Still further, the semiconductor operation layer (40) is formed to be as a laminated layer of an electron transit layer (41) that is formed of a GaN as an undope, of an electron supplying layer (42) that is formed of an AlGaN as Si doped to be an (n) type, and of a contact layer (43) that is formed of a GaN as an (n+) type one after the other in such the order. Still further, each of the source electrode (51) and the drain electrode (52) has a laminated structure of a Ti/Al respectively, and then each of those is formed on to the contact layer (43). Still further, the gate electrode (53) has a laminated structure of a Pt/Au, and then the same is formed on to the electron supplying layer (42) via an open part (43a) that is formed on to a contact layer (43).

Still further, in the buffer layer (20) first semiconductor layers from (211) through (218) that are individually formed of a GaN as an undope and each of second semiconductor layers (22) are laminated as alternately. And then as defining a pair of the first semiconductor layer and the second semiconductor layer that are adjacent to each other to be as a composite lamination the buffer layer (20) comprises eight layers of such the composite laminations. Furthermore, due to the existence of the intercalated layer (30) it becomes able to prevent from a formation of an alloy, though in a case where the first semiconductor layer (211) that is formed of the GaN is to be formed directly on to the substrate (10) that is formed of Si the Ga and the Si therein cannot help but form such the alloy.

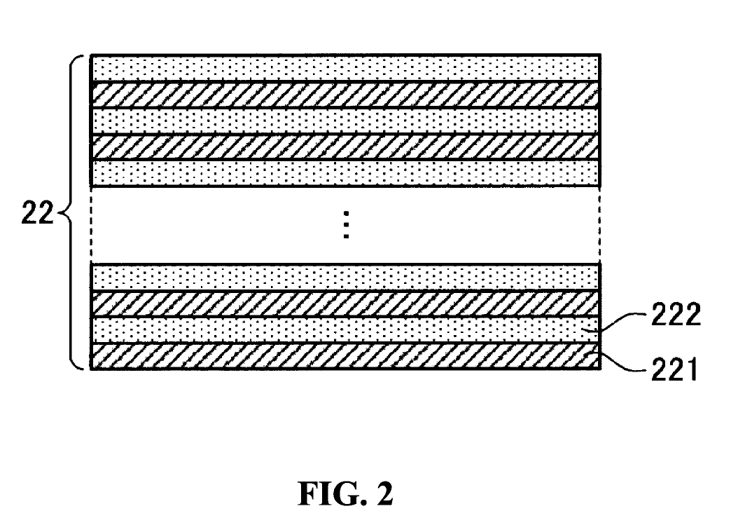

Next, FIG. 2 is a cross sectional view for exemplary showing a detailed structure of the second semiconductor layer (22) that is shown in FIG. 1. And then such the second semiconductor layer (22) is designed to have a multi layered structure in which a third semiconductor layer (221) that is formed of a GaN as an undope and a fourth semiconductor layer (222) that is formed of an AN as an undope are laminated as alternately with twelve layers for each, that is shown in FIG. 2. Moreover, such the third semiconductor layer (221) has a layer thickness to be as equivalent to that of the fourth semiconductor layer (222).

In the meantime, whole of the dislocation reduction layer (60) is formed of a GaN as an undope. Further, such the dislocation reduction layer (60) comprises a lower layer region (61) and an upper layer region (62) that have an interface (60a) of a concave and convex shape.

Still further, the substrate (10) that is formed of Si has a lattice constant to be as 0.384 nanometer, and the same has a coefficient of thermal expansion to be as 3.59 times 10⁻⁶/K. And in the meantime, each of the first semiconductor layers from the (211) through the (218) that are individually formed of the GaN and the dislocation reduction layer (60) has the lattice constant to be as 0.3189 nanometer respectively, which is smaller than that of the substrate (10), and each thereof has the coefficient of thermal expansion to be as 5.59 times 10⁻⁶/K respectively, which is larger than that of the substrate (10). And in the meantime, the intercalated layer (30) that is formed of the AN has the lattice constant to be as 0.3112 nanometer, which is smaller than that of the individual first semiconductor layers from the (211) through the (218), and the same has the coefficient of thermal expansion to be as 4.2 times 10⁻⁶/K, which is larger than that of the substrate (10). And in the meantime, the second semiconductor layer (22) has an average of the lattice constants at the inner side of such the layers to be as 0.31505 nanometer, which is smaller than that of the individual first semiconductor layers from the (211) through the (218), and the same has an average of the coefficients of thermal expansion at the inner side of such the layers to be as 4.895 times 10⁻⁶/K, which is larger than that of the substrate (10).

Still further, a layer thickness of the intercalated layer (30) is designed to be such as approximately forty nanometers or the like. Still further, the first semiconductor layers from the (211) through the (218) are formed for each of the layer thicknesses to be increased as an exponential function toward a lamination direction. As more specifically the first semiconductor layer (211) as the first layer from the substrate (10) has the layer thickness to be as approximately 300 nanometers, and then each of the first semiconductor layers from the (212) through the (218) has the layer thickness to be as approximately 352.7 nanometers, 422.8 nanometers, 520.1 nanometers, 663.2 nanometers, 891.9 nanometers, 1306 nanometers and 2237 nanometers respectively, that such the layer thickness becomes to be thicker toward the lamination direction. In the meantime, in the second semiconductor layer (22) the layer thickness of each of the third semiconductor layer (221) and the fourth semiconductor layer (222) that configure the second semiconductor layer (22) is designed to be as approximately 2.5 nanometers respectively. And then thereby becoming a total of the layer thicknesses to be as approximately sixty nanometers for each respectively. And then therefore a layer thickness of the buffer layer (20) becomes to be as approximately 7.18 micrometers. Furthermore, a layer thickness of the dislocation reduction layer (60) is determined here to be as approximately 1500 nanometers. And in the meantime a layer thickness of the semiconductor operation layer (40) is determined here to be as approximately 1.35 micrometers. And then therefore a total of the layer thickness of the epitaxial layer in addition to that of the buffer layer (20) becomes to be approximately 10.05 micrometers.

Next, such the field effect transistor (100) is manufactured by the following steps of: forming the intercalated layer (30), the dislocation reduction layer (60), the buffer layer (20) and then the semiconductor operation layer (40) one after the other in such the order on to the substrate (10) that has a diameter of such as four inches or the like by making use of the process of the epitaxial crystal growth of such as the method of the MOCVD or the like; forming the source electrode (51), the drain electrode (52) and the gate electrode (53); and then thereafter separating into each of the devices.

Moreover, it becomes able to manufacture such the field effect transistor (100) with having the warp to be as smaller and with having the ON resistance to be as lower, by being provided such the configuration that is described above.

The further explanation will be described in detail below. And regarding the reduction of the ON resistance of such the field effect transistor (100) will be described in detail in the first instance, and then regarding the reduction of the warp will be described in detail at the next.

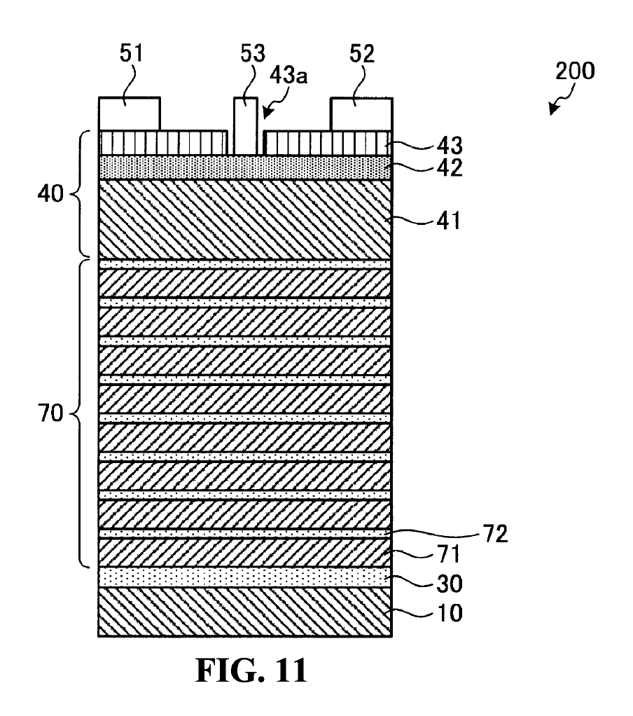

Here, in a case of the buffer layer that has a conventional structure of such as shown in FIG. 11 or the like a density of an edge dislocation in an electron transit layer is in an order of 1010 cm⁻², that is a value to be as good. In the meantime however, such the density of the edge dislocation gives a negative effect as excessively on an electron mobility. And then therefore it becomes important as extremely to reduce such the density of the edge dislocation in order to prevent from the reduction of the electron mobility, so as to perform the further reduction of the ON resistance.

On the contrary, in accordance with such the field effect transistor (100) it becomes able to perform the reduction of the dislocation that is generated at the vicinity of the substrate (10), by making use of the dislocation reduction layer (60). Moreover, by making use of the second semiconductor layer (22) it becomes able to prevent the increase of the dislocations at the inner side of the buffer layer (20). And then thereby becoming able to reduce the dislocation density as extremely in the electron transit layer (41). And then as a result it becomes able to obtain the ON resistance to be as extremely lower.

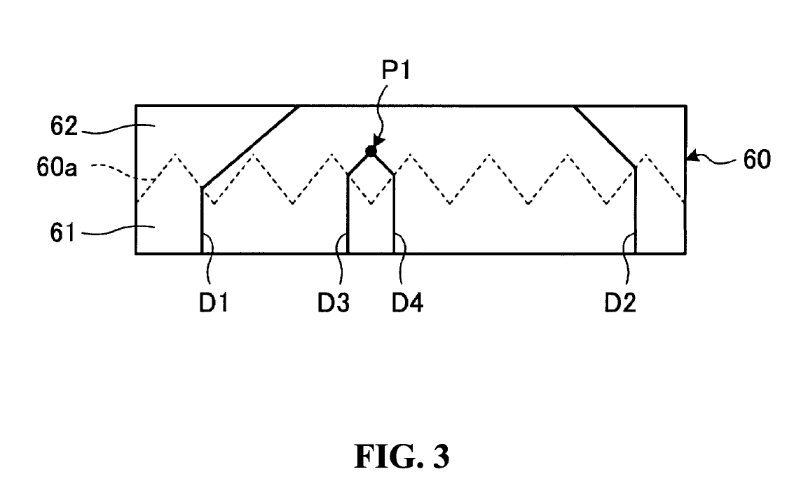

In the first instance, an advantage of the reduction of the dislocation by making use of the dislocation reduction layer (60) will be described in detail below. Here, FIG. 3 is an explanatory drawing for showing a function of the dislocation reduction layer (60). And then the threading dislocations as D1 and D2 that are individually generated at the vicinity of the substrate (10) extend toward the lamination direction in the lower layer region (61) of the dislocation reduction layer (60), however, the same is bended at an inclined face of the interface (60a) as the concave and convex shape, and the same becomes to be extending in the upper layer region (62), and then the same becomes to extend to the buffer layer (20) that locates directly above the dislocation reduction layer (60), that are shown in FIG. 3.

Here, threading dislocations as D3 and D4 are individually defined to be as the threading dislocations that individually have Burgers vectors that are in a direction to be as opposite to each other. And then each of such the threading dislocations as the D3 and the D4 extends toward an upper side of the lower layer region (61), and then the same is bended at the inclined face of the interface (60a), but the same runs into each other at a point P1 at the inner side of the upper layer region (62). Moreover, such the threading dislocations as the D3 and the D4 are to be disappeared at the point P1 and then the same are not to be reached to the buffer layer (20) because the same individually have the Burgers vectors that are in the direction to be as opposite to each other. Or, even if the same are not to be disappeared at the point P1 a magnitude of such the Burger vector becomes to be smaller, and then it becomes easier for such the threading dislocations to be disappeared on the way of extending toward the further upper side. And thus it becomes able to perform the reduction of the dislocations by making use of the dislocation reduction layer (60).

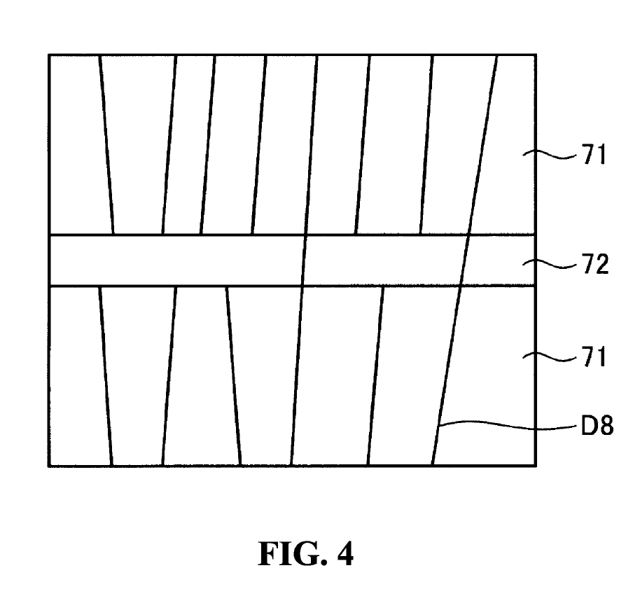

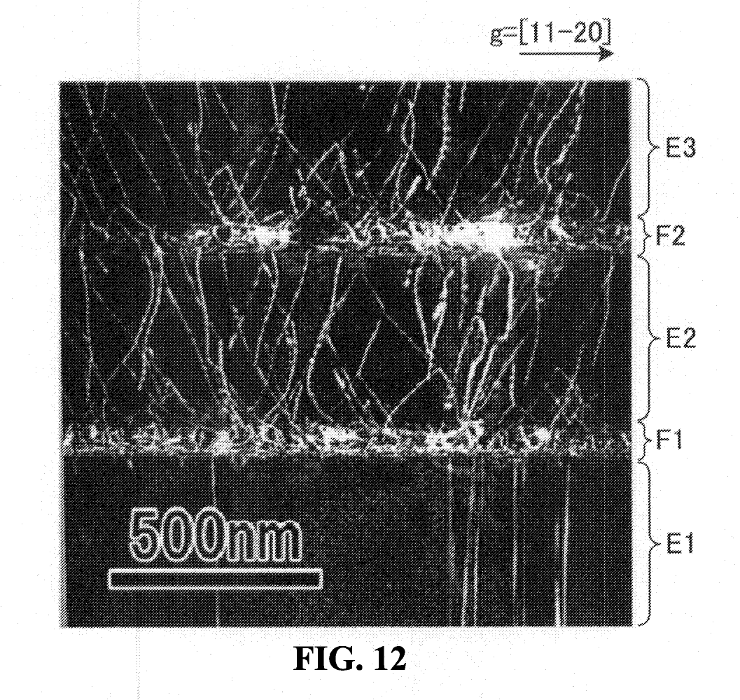

Next, an advantage of the prevention from the increase of the dislocation by making use of the second semiconductor layer (22) will be described in detail below. Here, in the AlN layer of the buffer layer the threading dislocations are increased, as shown in FIG. 12 that is described above. FIG. 4 is a drawing for exemplary showing an appearance of which a threading dislocation is increasing in accordance with a field effect transistor (200) that is shown in FIG. 11. And then a threading dislocation D8 is drawing from a GaN layer (71) that is a lower side in the paper toward an upper side, and a part of the same becomes to pass through an AlN layer (72) and then to draw to the GaN layer (71) that is the upper side in the paper, in the meantime however, most of the threading dislocations as the D8 are disappeared at an interface of between the AlN layer (72) and each of the GaN layer (71) or at an inner side of the AlN layer (72), that are shown in FIG. 4. In the meantime however, new threading dislocations are generated and increased on the other hand at the inner side of the AlN layer (72), and then such the dislocations become to be drawing to the GaN layer (71) at the upper side in the paper. And then as a result in accordance with such the field effect transistor (200) it is not able to realize the reduction of the dislocation density to be as sufficiently in the electron transit layer (41), and then it is not able to obtain the ON resistance to be lower as sufficiently.

The reason why the threading dislocation (L) is increased at the inner side of the AlN layer (72) may be considered as below. That is to say, it may be considered that the AlN layer (72) that is grown on the GaN layer (71) is to be grown with becoming to have a surface from a smooth shape to an island shape that has a concave and a convex in a case of growing to have a layer thickness to be thicker, due to a difference of the lattice constant of the GaN and that of the AlN, and then that as a result there becomes to be occurred a slight shift in a crystal orientation of the AlN for between each of such the island, and hence that the dislocation density becomes to be increased, and then that such the threading dislocations are propagated through the inner side of the GaN layer (71) which is laminated on to such the layer. On the contrary, if the layer thickness of such the AlN layer (72) is formed to be thinner it becomes able to prevent from the increase of such the dislocation density. However, it is not able to maintain the advantage of the suppressing of the warp that will be described later in a case of only performing the lamination of such the layer to be thinner. Moreover, in a case where the AlN layer (72) is replaced to an AlGaN layer that has a lattice constant to be further close to that of the GaN layer (71) the increase of the dislocation density becomes to be occurred in such the AlGaN layer either.

In the meantime however, in accordance with the buffer layer (20) in the field effect transistor (100) in accordance with the present first embodiment the second semiconductor layer (22) that corresponds to the AlN layer (72) comprises the third semiconductor layer (221) which is formed of the GaN as the undope and which has the layer thickness to be as thinner and the fourth semiconductor layer (222) which is formed of the AlN as the undope and which has the layer thickness to be as thinner that are formed into a multi layered lamination as alternately. And then as a result each of such the fourth semiconductor layers (222) is not to be grown into an island shape, and then a surface of the same becomes to be smooth. And hence it becomes able to prevent from the excessive increase of the dislocation density. Further, such the second semiconductor layer (22) is equivalent to the AlGaN layer from a macroscopic point of view. And then therefore it becomes able to function the advantage of suppressing the warp. And then by forming the same with having a layer thickness to be a desired thickness it becomes able to maintain as sufficiently such the advantage of suppressing the warp.

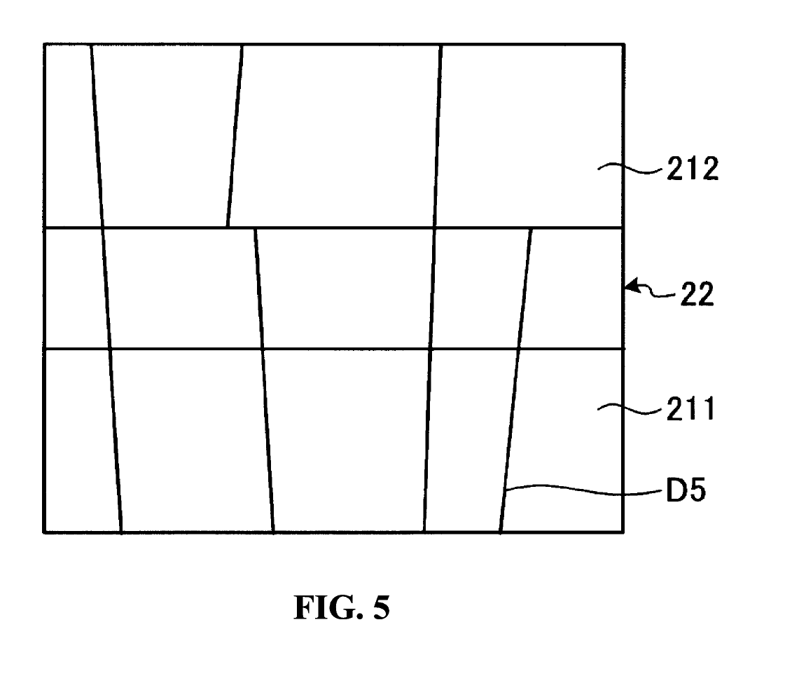

Here, FIG. 5 is a drawing for exemplary showing an appearance of which an increasing of a threading dislocation is prevented in accordance with the field effect transistor (100) that is shown in FIG. 1. And then a threading dislocation D5 is drawing from the first semiconductor layer (211) toward an upper side, and in the meantime, the number of such the dislocations is decreasing due to the effect of the dislocation reduction layer (60), that is shown in FIG. 5. Moreover, a part of such the threading dislocations are passing through the second semiconductor layer (22) and then draw to the first semiconductor layer (212). In the meantime however, most of the threading dislocations D5 are disappeared at an interface of the second semiconductor layer (22) and each of the first semiconductor layers as the (211) and the (212) respectively, or at the inner side of the second semiconductor layer (22). And then the threading dislocations D5 become to be decreased as extremely that are generated at the inner side of the second semiconductor layer (22) and then that are drawing to the first semiconductor layer (212).

That is to say, in accordance with such the field effect transistor (100) the dislocations become to be decreased by making use of the dislocation reduction layer (60), that are generated at the vicinity of the substrate (10). Further, the dislocations that are decreased once are prevented from increasing again at the inner side of the buffer layer (20) by making use of the second semiconductor layer (22). And hence it becomes able to reduce further the dislocation density in the electron transit layer (41). And then therefore it becomes able to perform the reduction of the ON resistance to be as lower.

Furthermore, in accordance with such the second semiconductor layer (22) that has such the multi layered lamination structure it becomes able to set up a speed of such the lamination growth to be as extremely fast with comparing to that of an AlN layers or of an AlGaN that individually have a layer thickness as equivalent to each other, respectively. And then therefore it becomes able to obtain an improvement of a productivity of such the field effect transistor (100).

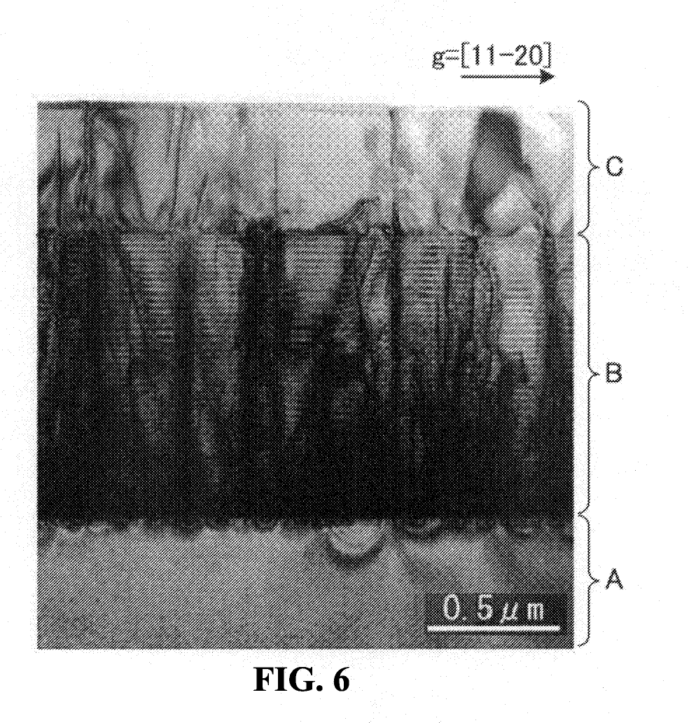

Next, FIG. 6 is a view for showing a TEM image regarding a cross section of a field effect transistor that comprises a structure of a multilayer laminated layer (B) and a GaN layer (C) as an undope one after the other in such the order on to a substrate (A) that is formed of Si. And then such the multilayer laminated layer (B) is designed to be as a layer in which fifty layers for each of GaN layers as the undope, that individually have the layer thickness of approximately ten nanometers respectively, and of AlN layers as the undope, that individually have the layer thickness of approximately ten nanometers respectively, are formed in a multi layered lamination as alternately, that is similar to the second semiconductor layer (22) in accordance with the first embodiment. Moreover, in accordance with FIG. 6 a dislocation is generated at an interface of between the substrate (A) and the multilayer laminated layer (B), that is designated by making use of a black line. In the meantime however, the dislocation density becomes to be decreased at an inner side of the multilayer laminated layer (B), and then the same becomes to be decreased as extremely at an interface of between the multilayer laminated layer (B) and the GaN layer (C). Further, it becomes able to prevent from increasing the dislocations at the inner side of the multilayer laminated layer (B). Furthermore, in accordance with the second semiconductor layer (22) in the field effect transistor (100) that is shown in FIG. 1 it becomes able to realize the reduction of the dislocation density and the prevention from the increase of the dislocation, which is similar to that in accordance with such the multilayer laminated layer (B) in the field effect transistor that is shown in FIG. 6.

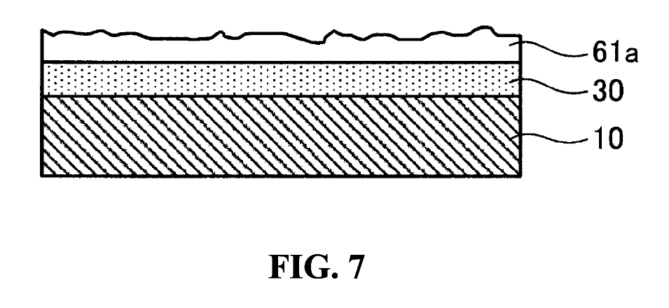

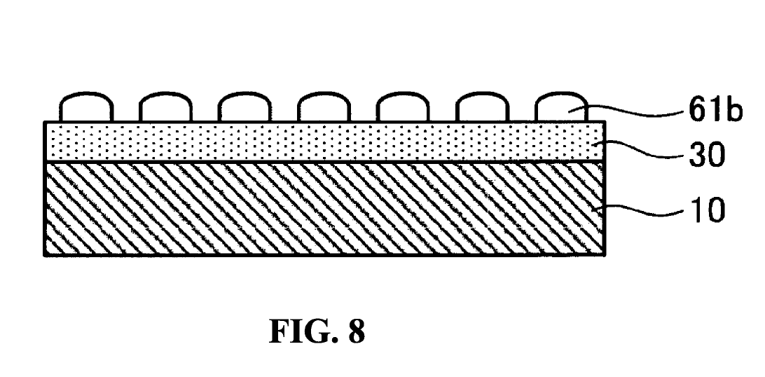

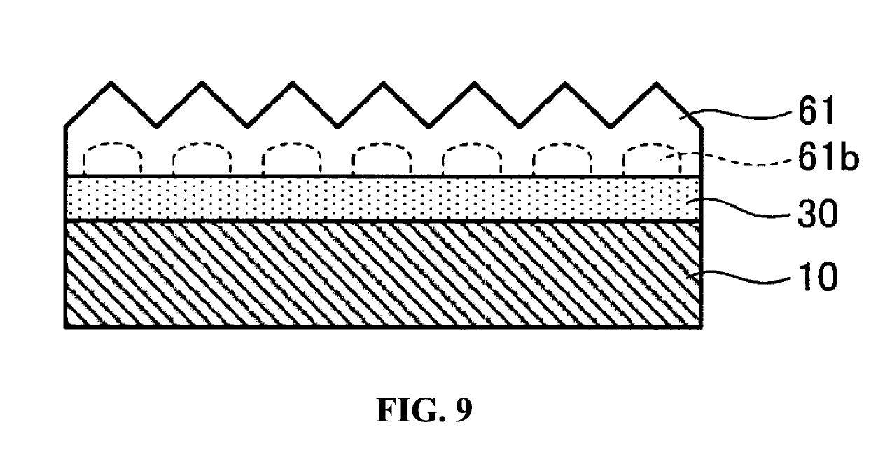

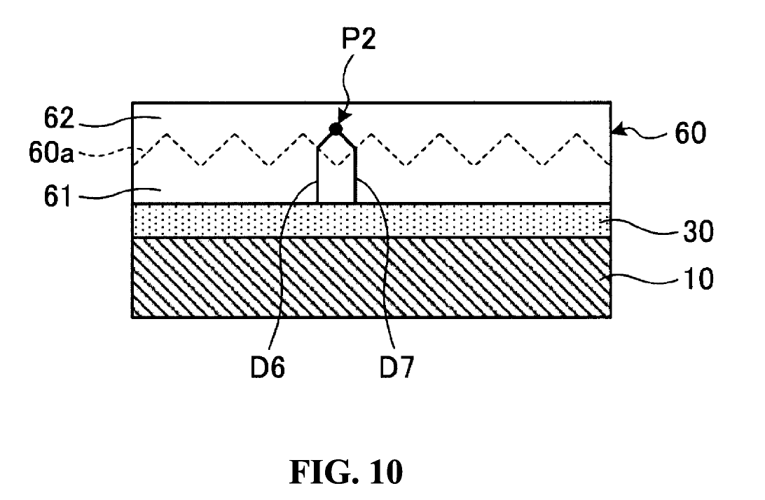

Next, the dislocation reduction layer (60) is to be formed in accordance with such as the following steps or the like. Here, from FIG. 7 through FIG. 10 are explanatory drawings for showing one example of a process of forming the dislocation reduction layer (60). And then in the first instance a temperature of a substrate is set up to be as between 400° C. and 600° C., and then an amorphous layer (61a) is to be formed of GaN as an undope to have a layer thickness of approximately 400 nanometers at the maximum on to the intercalated layer (30), that are shown in FIG. 7. Next, by raising the temperature of the substrate to between 850° C. and 950° C. a growth core (61b) is to be formed into an island shape from the amorphous layer (61a), that is shown in FIG. 8. And then such the growth core (61b) comprises an island structure which has a plurality of facet faces that are individually inclined against a surface of the intercalated layer (30). Next, the lower layer region (61) is to be formed of a GaN as the undope with having a layer thickness of approximately 1000 nanometers at the maximum so as to cover the growth core (61b), that is shown in FIG. 9. And then a most top surface of the lower layer region (61) becomes to have a concave and convex shape due to a reflection of the shape of the growth core (61b). Next, by raising the temperature of the substrate to between 950° C. and 1050° C. the upper layer region (62) is to be formed of a GaN as the undope on to the lower layer region (61), and then the same is designed to be as the dislocation reduction layer (60), that is shown in FIG. 10. Moreover, the formation of such the upper layer region (62) is performed under a condition in order to accelerate a crystal growth toward a longitudinal direction. And hence a most top surface of the upper layer region (62) becomes to be smooth. Further, a threading dislocation becomes to draw in a vertical direction against a growth face in such a case. And hence the threading dislocations of D6 and D7 become to be bended at the most top surface of the lower layer region (61), that is to say, at the interface (60a). Still further, each of such the threading dislocations as the D6 and the D7 has the Burgers vector that has a direction as opposite to each other. And then such the dislocations become to be disappeared at a time when the same runs into each other at a point P2.

Furthermore, the lower layer region (61) and the upper layer region (62) are individually formed of a semiconductor material that has a composition to be as similar to each other. And then even at the interface (60a) of therebetween such as the crystal structure or the like is continuous. In the meantime however, it is able to determine the location and the shape of the interface (60a) as easily, because it is able to observe an appearance of which the interface is existing on which a plurality of the threading dislocations are bending in a case of performing the observation of a cross section of such the dislocation reduction layer (60) by making use of such as an electron microscope or the like.

Next, regarding a withstanding against a higher voltage of such the field effect transistor (100) to be as higher and regarding a tendency of which the warp becomes to be smaller will be described in detail below. And then hereinafter a case where the substrate (10) becomes to be warped as a convex shape is defined to be warped in a plus direction, and in the meantime a case where the same becomes to be warped as a concave shape is defined to be warped in a minus direction.

Moreover, at a period of manufacturing such the field effect transistor (100) the intercalated layer (30), the buffer layer (20) and the semiconductor operation layer (40) are formed at a temperature of the substrate to be as approximately between 1000° C. and 1100° C. respectively. And then in the case of forming the intercalated layer (30) on to the substrate (10) the warp is to be generated in the minus direction, because such the intercalated layer (30) has the lattice constant to be as smaller than that of the substrate (10). Next, in the case of forming the first semiconductor layer (211) as the first layer on to the intercalated layer (30) via the dislocation reduction layer (60) the warp is to be generated in the plus direction at the period when the first semiconductor layer (211) has the layer thickness to be as still thinner, because such the first semiconductor layer (211) has the lattice constant to be as larger than that of the intercalated layer (30). On the contrary however, at the period when such the layer thickness of the first semiconductor layer (211) becomes to be thicker than or equal to a certain thickness the warp becomes to be generated in the minus direction so as to cancel the warp in the plus direction, because the lattice constant of the first semiconductor layer (211) is smaller than that of the substrate (10). And then hereinafter such the layer thickness of the semiconductor layer is referred to as a critical thickness at the time when the direction of the warp becomes to be reversed of which the semiconductor layer is to generate with corresponding to the epitaxial substrate. That is to say, the critical thickness means a layer thickness at which the warp becomes to have the maximum point with corresponding to the variation of the thickness of the semiconductor layer. Furthermore, in the case of the structure in accordance with the first embodiment the critical thickness for the first semiconductor layer (211) is determined here to be as approximately 200 nanometers.

Next, in the case of forming the second semiconductor layer (22) on to the first semiconductor layer (211) the warp becomes to be generated in the minus direction, because such the second semiconductor layer (22) has the average of the lattice constants at the inner side of the layer to be smaller than that of the first semiconductor layer (211).

Next, in the case of forming the first semiconductor layer (212) on to the second semiconductor layer (22) the warp becomes to be generated in the plus direction at the period of the first semiconductor layer (212) to have the layer thickness to be as still thinner, and then the warp becomes to be generated in the minus direction at the period when the layer thickness becomes to be thicker than or equal to the certain critical thickness, that are similar to the case in accordance with the first semiconductor layer (211). On the contrary however, such the critical thickness of the first semiconductor layer (212) becomes to be thicker than the critical thickness of the first semiconductor layer (211). And then the reason is considered to be because in such the case of the first semiconductor layer (212) the layer is affected by the intercalated layer (30) that is formed at the lower side thereof and by each of the semiconductor layers (the ground layer) of the first semiconductor layer (211) and of the second semiconductor layer (22).

Here, in a case where the layer thickness of the first semiconductor layer (212) is equivalent to the layer thickness of the first semiconductor layer (211) the warp toward the minus direction that is to be generated in the first semiconductor layer (212) becomes to be smaller. On the contrary however, in accordance with the present first embodiment the first semiconductor layer (212) is formed with having the layer thickness to be as thicker than that of the first semiconductor layer (211), that is described above. And then as a result the warp that is to be generated in the minus direction in the first semiconductor layer (212) becomes to be maintained as largely even in the case where the critical thickness of the first semiconductor layer (212) becomes to be thicker than the critical thickness of the first semiconductor layer (211).

Ditto, as forming the first semiconductor layers of the (213) and then the (214) and the like with sandwiching the second semiconductor layer (22) the total of the layer thickness of the grand layers becomes to be thicker. And hence the critical thickness becomes to be thicker as well. On the contrary, in accordance with such the field effect transistor (100) the layer thickness becomes to be increased in the lamination direction with corresponding to the first semiconductor layers from the (213), the (214) to the (218). Moreover, each of such the first semiconductor layers from the (213), the (214) to the (218) is formed with having the layer thickness to be as thicker than the critical thickness at each of the corresponding locations for the lamination as well respectively. And then as a result the warp that is to be generated in the minus direction in each of the first semiconductor layers from the (211) through the (218) becomes to be maintained as largely. And hence the warp that is to be generated in the plus direction becomes to be canceled, and then the same becomes to be smaller as extremely.

At the last step the semiconductor operation layer (40) is to be formed, and then the processing of the epitaxial growth is finished. In the meantime however, even in the semiconductor operation layer (40) the warp is to be generated in the plus direction as totally. And then thereafter the temperature of the substrate is to be cooled from between 1000° C. and 1100° C. to a room temperature. And hence the warp becomes to be generated in the minus direction as decreasing the temperature of the substrate, because each of the buffer layer (20), the dislocation reduction layer (60), the intercalated layer (30) and of the semiconductor operation layer (40) has the coefficient of thermal expansion to be as larger with comparing to that of the substrate (10), respectively. And then therefore the final amount of the warp becomes to be as a small value. Further, it becomes able to form the epitaxial layers with having the total of the layer thickness to be as thicker, with suppressing the warp by making use of such the above mentioned function. And then therefore it becomes able to obtain the withstanding against the higher voltage to be as higher.

And thus in such the manner that is described above in accordance with such the field effect transistor (100) it becomes able to decrease the warp to be as smaller, and it becomes able to obtain the withstanding to be as higher against the higher voltage as well, because the total of the layer thickness of the epitaxial layers on the substrate (10) is thicker. Furthermore, in each of the first semiconductor layers from the (211) through the (218) the warps are canceled to each other. And then therefore it becomes able to obtain an advantage as well, of which the strain that is existing at the inner side becomes to be decreased as extremely.

### EXAMPLE AND COMPARATIVE EXAMPLE

A field effect transistor is manufactured as an example in accordance with the present invention, that comprises a structure which is similar to that of the field effect transistor (100) in accordance with the first embodiment. And in the meantime another field effect transistor is manufactured as a comparative example, that comprises a structure in which the dislocation reduction layer is not formed and the second semiconductor layer is replaced to an AN layer which has a layer thickness of approximately sixty nanometers in accordance with the field effect transistor (100). And then thereafter a dislocation density in an electron transit layer of each of the field effect transistors in accordance with such the example and with the comparative example is measured by making use of the TEM.

And then as a result, in the field effect transistor in accordance with the comparative example the density of the edge dislocation in the electron transit layer is measured to be as approximately two times 10¹⁰ cm⁻², and the density of a spiral dislocation is measured to be as approximately three times 10⁹ cm⁻². On the contrary however, in the field effect transistor in accordance with the example the density of the edge dislocation in the electron transit layer is measured to be as approximately 0.5 times 10¹⁰ cm⁻², and the density of the spiral dislocation is measured to be as approximately one times 10⁹ cm⁻², that are individually further excellent.

Here, in accordance with the present first embodiment the layer thickness of the first semiconductor layer (211) is approximately 300 nanometers, that is the most thinnest. On the contrary however, if the same is thicker than or equal to approximately 400 nanometers it is further preferable because it is able to obtain the amount of the warp that is to be generated in the minus direction to be larger as sufficiently. Moreover, it is desirable if the layer thickness of each of the first semiconductor layers from the (211) through the (218) is thinner than or equal to 3000 nanometers, because the productivity becomes to be higher due to the amount of time for performing the growth becomes to be shorter as sufficiently.

Further, it is desirable if the layer thickness of the second semiconductor layer (22) is thicker than or equal to five nanometers but thinner than or equal to 500 nanometers, because it becomes able to suppress the strain as sufficiently that is existing at the inner side of each of the first semiconductor layers from the (211) through the (218).

Still further, if each of the third semiconductor layer (221) and the fourth semiconductor layer (222) has the layer thickness to be as thinner than or equal to fifty nanometers the growth of such the layer becomes to be as a two dimensional growth with having a surface to be as smooth, respectively. And hence the dislocation becomes seldom to be increased at the inner side of the layer, respectively. And in the meantime if such the layer has the thickness to be as thicker than or equal to 0.5 nanometer it is desirable because it becomes able to obtain the advantage of the reduction of the warp as sufficiently and then because it becomes able to realize the epitaxial substrate that has the warp to be as smaller and then that is further smooth.

Still further, if the sum of the number of the layers of the third semiconductor layers (221) and the fourth semiconductor layers (222) in the second semiconductor layer (22) is between five and thirty it is desirable because it becomes able to suppress as sufficiently the strain that is existing at the inner side of each of the first semiconductor layers from the (211) through the (218).

Still further, if the average of the lattice constants at the inner side of the layers in the second semiconductor layer (22) is smaller as excessively the dislocation density becomes to be increased as easily, and in the meantime if the same is larger as excessively the advantage of the reduction of the warp becomes to be decreased. And then therefore it is desirable for the average of the lattice constants at the inner side of the layers in the second semiconductor layer (22) to be as approximately the mean value of between the lattice constant of each of the first semiconductor layers from the (211) through the (218) and the lattice constant of the fourth semiconductor layer (222). Still further, in order to set up the average of the lattice constants at the inner side of the layers in the second semiconductor layer (22) to be as a preferred value in such the manner it may be available to perform as properly an adjustment of such as a ratio of between the layer thickness of the third semiconductor layer (221) and the layer thickness of the fourth semiconductor layer (222) or the like.

Still further, the layer thickness of each of the first semiconductor layers from the (211) through the (218) and of the every layer of the second semiconductor layers (22) and of the intercalated layer (30) is not to be limited to each of the corresponding values in accordance with the first embodiment that is described above, respectively. And then it is able to set up as properly with corresponding to such as the composition of the same, a difference of the lattice constant and a difference of the coefficient of thermal expansion from that of the substrate (10) respectively, a withstanding against a higher voltage that is required to a device, an amount of the warp that is allowed for the device, or the like.

Still further, it is desirable for the layer thickness of the dislocation reduction layer (60) to be as thicker than or equal to 100 nanometers, in order to form into the concave and convex shape as sufficiently so as to obtain the advantage of the reduction of the dislocations as sufficiently, and in order to form the same into a shape as smoother. And in the meantime it is desirable for the same to be as thinner than or equal to 3000 nanometers in order to enhance the productivity.

Still further, in the field effect transistor (100) in accordance with the first embodiment that is described above the dislocation reduction layer (60) is formed at the location as directly under the buffer layer (20). However, a location of the dislocation reduction layer (60) is not to be limited to such the location. And then if the same is formed at any location at the inner side of the buffer layer (20) it becomes able to function such the advantage of the reduction of the dislocations.

For example, if a configuration is designed in which such the dislocation reduction layer (60) is formed at a location of which at least any one of the first semiconductor layers is intercalated for between the substrate (10) the threading dislocation that is generated at the vicinity of the substrate (10) becomes to be decreased once at the inner side of at least any one of such the first semiconductor layers. And hence it becomes easier for the threading dislocations to be further disappeared in the dislocation reduction layer (60). And then therefore it is desirable because it becomes able to obtain the ON resistance to be as further lower. Still further, even if a configuration is designed in which such the dislocation reduction layer (60) is formed at a location of which at least any one of the first semiconductor layers and/or of the second semiconductor layers is intercalating for between the substrate (10) it becomes easier for the threading dislocations to be disappeared in such the dislocation reduction layer (60) as well.

Still further, it may be available for any of the first semiconductor layers in the buffer layer (20) to be separated into two layers of an upper layer and a lower layer, and then it may be available for such the dislocation reduction layer (60) to be formed so as to intercalate in between such the two layers.

Still further, it may available to design a structure in which the dislocation reduction layer comprises the following. In the first instance a lower layer region is to be formed, that has a surface of a concave and convex shape and that is formed of a GaN as an undope. And then thereafter a first warp reduction layer that is formed of an AlN as an undope and a first upper layer region that is formed of a GaN as an undope and a second warp reduction layer that is formed of an AlN as an undope and then a second upper layer region that is formed of a GaN as an undope are to be laminated one after the other in such the order on to such the lower layer region. And then by making use of such the structure a threading dislocation that is extending from the lower side becomes to be bended at an inclined face of an interface, because such the interface between the lower layer region and the first warp reduction layer has a concave and convex shape. And hence it becomes able to decrease the density of the threading dislocations in the electron transit layer due to the advantage which is similar to that in accordance with the dislocation reduction layer (60). And then therefore it becomes able to perform the reduction of the ON resistance to be as lower. Still further, in accordance with such the dislocation reduction layer that comprises such the structure in which the lower layer region that is formed of the GaN, the first upper layer region, the second upper layer region, the first warp reduction layer that is formed of the AN and the second warp reduction layer are laminated as alternately. And hence it becomes able to suppress such the warp due to the function which is similar to that in accordance with the buffer layer (20), even in the case where the layer thickness of the dislocation reduction layer becomes to be thicker. Still further, the number of such the dislocation reduction layers is not to be limited to two, and then it may be available if the same is one or a plurality thereof. Still further, it is able to form such the dislocation reduction layer that comprises such the structure by making use of the process which is similar to that for the dislocation reduction layer (60) with changing as properly a material for the growth.

Still further, in the case of forming the dislocation reduction layer it may be available as well to form a growth core as an island shape with having a layer thickness to be as approximately thinner than or equal to five nanometers that is to be formed of a silicon nitride or of a silicon oxide, and then thereafter to form a lower layer region thereon that is to be formed of a GaN as an undope so as to cover such the growth core, and then thereafter to form an upper layer region that is to be formed of a GaN as an undope thereon. And then in accordance with such the dislocation reduction layer that is formed by making use of such the process a concave and convex shape of an interface at between the lower layer region and the upper layer region becomes to be formed due to the growth core as the island shape that is formed of the silicon nitride or of the silicon oxide. Still further, if a dislocation reduction layer is formed with making use of the silicon nitride or of the silicon oxide it becomes able to enhance the productivity of such the dislocation reduction layer, because it is easy for each of such the materials to form the growth core of the island shape at the initial stage of such the growth. Still further, it is able to form such the growth core of the island shape by making use of a method of vapor growth, such as any type of the CVD methods or the like.

Still further, in accordance with the first embodiment that is described above the substrate which is formed of Si is designed to be made use. However, it may be available to make use of a substrate that is formed of an SiC or a ZnO or the like. Still further, it is not to be limited in particular regarding a material for each of the region in the dislocation reduction layer, the warp reduction layer, the intercalated layer and for the semiconductor layers from the first through the fourth if the same is a compound semiconductor of a nitride system and also if each of a lattice constant and a coefficient of thermal expansion with including that of the substrate satisfies a predetermined relation, respectively. And then it may be available to set up a composition of each of the third and the fourth semiconductor layers so as to be proven true such as that an (x1) is smaller than an (x2), or the like, in a case where the composition of such the third semiconductor layer is expressed by a chemical formula of an Alₓ₁In_{y1}Ga_{1-x1-y1}Asᵤ₁Pᵥ₁N₁₋ᵤ₁₋ᵥ₁ (here 0≦x≦1, 0≦y1≦1, x1+y1≦1, 0≦u1≦1, 0≦v1≦1 and u1+v1≦1) and the composition of such the fourth semiconductor layer is expressed by a chemical formula of an Alₓ₂In_{y2}Ga_{1-x2-y2}Asᵤ₂Pᵥ₂N₁₋ᵤ₂₋ᵥ₂ (here 0≦x2≦1, 0≦y2≦1, x2+y2≦1, 0≦u2≦1, 0≦v2≦1 and u2+v2≦1) in the second semiconductor layer in accordance with the first embodiment that is described above.

Still further, in accordance with the first embodiment that is described above the semiconductor electronic device is designed to be as the field effect transistor of the HEMT type. However, the present invention is not to be limited to such the case. And then it is possible to apply to a various types of field effect transistors, such as an insulated gate type (a metal insulator semiconductor (an MIS) type, a metal oxide semiconductor (an MOS) type) or a Schottky gate (a metal semiconductor (an MES) type) or the like. Furthermore, it is possible to apply the present invention to every type of diodes, such as a Schottky diode or the like, in addition to such the field effect transistors. And then it becomes able to realize a diode to which the present invention is applied if a structure is designed in which a cathode electrode and an anode electrode are formed in the place of the source electrode (51), the drain electrode (52) and of the gate electrode (53) in the field effect transistor (100) in accordance with the first embodiment.

What is claimed is:

1. A semiconductor electronic device, comprising:
a substrate;
a buffer layer that comprises composite laminations of which a first semiconductor layer, that is formed of a compound semiconductor of a nitride system, that has a lattice constant to be as smaller than that of said substrate, and that has a coefficient of thermal expansion to be as larger than that of said substrate, and a second semiconductor layer that is formed of a compound semiconductor of a nitride system are formed as alternately on to said substrate;
a semiconductor operation layer that is formed of a compound semiconductor of a nitride system and that is formed on to said buffer layer; and
a dislocation reduction layer, which comprises a lower layer region and an upper layer region that are formed in between said substrate and said semiconductor operation layer and that comprise an interface of a concave and convex shape, at which a threading dislocation that draws from said lower layer region toward said upper layer region is bending at said interface, and which is formed of a compound semiconductor of a nitride system,
wherein said second semiconductor layer is comprised of a laminated layers as alternately of a third semiconductor layer that has a lattice constant to be as smaller than that of said substrate and that has a coefficient of thermal expansion to be as larger than that of said substrate, and of a fourth semiconductor layer that has a lattice constant to be as smaller than that of said third semiconductor layer and that has a coefficient of thermal expansion to be as larger than that of said substrate, and an average of said lattice constants in said second semiconductor layer is smaller than that of said first semiconductor layer, and an average of said coefficients of thermal expansion said second semiconductor layer is larger than that of said substrate.

2. The semiconductor electronic device according to claim 1,
wherein it is proven true that an (x1) is smaller than an (x2), in a case where a composition of said third semiconductor layer is expressed by a chemical formula of an Alₓ₁In_{y1}Ga_{1-x1-y1}Asᵤ₁Pᵥ₁N₁₋ᵤ₁₋ᵥ₁ (here 0≦x1≦1, 0≦y1≦1, x1+y1≦1, 0≦u1≦1, 0≦v1≦1 and u1+v1≦1) and a composition of said fourth semiconductor layer is expressed by a chemical formula of an Alₓ₂In_{y2}Ga_{1-x2-y2}Asᵤ₂Pᵥ₂N₁₋ᵤ₂₋ᵥ₂ (here 0≦x2≦1, 0≦y2≦1, x2+y2≦1, 0≦u2≦1, 0≦v2≦1 and u2+v2≦1).

3. The semiconductor electronic device according to claim 1,
wherein said third semiconductor layer has a layer thickness to be as thicker than or equal to 0.5 nanometer, but thinner than or equal to fifty nanometers.

4. The semiconductor electronic device according to claim 1, wherein said fourth semiconductor layer has a layer thickness to be as thicker than or equal to 0.5 nanometer, but thinner than or equal to fifty nanometers.

5. The semiconductor electronic device according to claim 1,
wherein said second semiconductor layer has a layer thickness to be as thicker than or equal to five nanometers, but thinner than or equal to 500 nanometers.

6. The semiconductor electronic device according to claim 1,
wherein a sum of the number of said layers of said third semiconductor layers and said fourth semiconductor layers in said second semiconductor layer is between five and thirty.

7. The semiconductor electronic device according to claim 1,
wherein said average of said lattice constants of said second semiconductor layer is smaller than or equal to a mean value of said lattice constant of said first semiconductor layer and said lattice constant of said fourth semiconductor layer.

8. The semiconductor electronic device according to claim 1,
wherein said substrate is comprised of any one of silicon and silicon carbide and zinc oxide.

9. The semiconductor electronic device according to one of claims 1 to 8, further comprising:
an intercalated layer, that is formed directly on to said substrate, that has a lattice constant to be as smaller than that of said first semiconductor layer, that has a coefficient of thermal expansion to be as larger than that of said substrate, and that is formed of a compound semiconductor of a nitride system.

10. A process of manufacturing a semiconductor electronic device, comprising the steps of:
forming a buffer layer on to a substrate as a processing of a formation of said buffer layer, that is to comprise composite laminations of which a first semiconductor layer, that is to be formed of a compound semiconductor of a nitride system, that is to have a lattice constant to be as smaller than that of said substrate, and that is to have a coefficient of thermal expansion to be as larger than that of said substrate, and a second semiconductor layer that is to be formed of a compound semiconductor of a nitride system are to be formed as alternately; and
forming a semiconductor operation layer as a processing of a formation of said semiconductor operation layer, that is to be formed of a compound semiconductor of a nitride system and that is to be formed on to said buffer layer, wherein said processing of said formation of said buffer layer further comprises a processing of a formation of a dislocation reduction layer in order to form a lower layer region at any location at an inner side of said buffer layer that is to be formed of a compound semiconductor of a nitride system and that is to comprise a most top surface of a concave and convex shape, and in order to form an upper layer region that is to have a most top surface to be as smooth on to said lower layer region that is formed in such a manner,
at said processing of said formation of said buffer layer a third semiconductor layer that is to have a lattice constant to be as smaller than that of said substrate and that is to have a coefficient of thermal expansion to be as larger than that of said substrate and a fourth semiconductor layer that is to have a lattice constant to be as smaller than that of said third semiconductor layer and that is to have a coefficient of thermal expansion to be as larger than that of said substrate are to be laminated as alternately, and
said second semiconductor layer is to be formed for an average of said lattice constants in order to be smaller than that of said first semiconductor layer and for an average of said coefficients of thermal expansion in order to be as larger than that of said substrate.

11. The process of manufacturing the semiconductor electronic device according to claim 10, comprising the additional step of:
forming an intercalated layer as a processing of a formation of said intercalated layer, that is to be formed directly on to said substrate, that is to have a lattice constant to be as smaller than that of said first semiconductor layer, that is to have a coefficient of thermal expansion to be as larger than that of said substrate, and that is to be formed of a compound semiconductor of a nitride system.
